(19) United States
(12) Patent Application Publication
(10) Pub. No.: US 2026/0229617 A1
(43) Pub. Date: Aug. 6, 2026

(54) SYSTEMS, METHODS, AND APPARATUSES FOR ASSESSING THE STATUS OF BATTERY CELLS INCLUDED IN A BATTERY HOUSING

(71) Applicant: Koolance, Inc., Auburn, WA (US)

(72) Inventors: Kioan Cheon, Auburn, WA (US); AnKuk Song, Anyang-si (KR)

(21) Appl. No.: 19/047,068

(22) Filed: Feb. 6, 2025

(51) Int. Cl. H01M 10/42; G01R 31/36; G01R 31/364; H01M 10/48; H01M 50/271; H01M 50/287

(52) U.S. Cl. CPC H01M 10/425; G01R 31/364; G01R 31/3646; H01M 10/4285; H01M 10/482; H01M 50/271; H01M 2010/4271; H01M 50/287

(57) ABSTRACT

In at least one embodiment, a battery management system includes a battery housing having one or more contacts, battery cells within the battery housing that are in contact with at least one contact of the battery housing and at least one contact of a lid, the lid for the battery housing that has one or more lid contacts and that can be moved such that a battery contact disengages with a lid contact, and one or more sensors that are electronically coupled to at least one lid contact. In operation, the one or more sensors sense data associated with the status of one or more battery cells. A processor may determine whether one or more battery cells is to be replaced based on the status data, and the battery cell may be replaced without removing other battery cells in the battery housing.

### BACKGROUND

### Technical Field

The present disclosure is directed to systems, methods, and apparatuses that store battery cells, such as disposable battery cells, rechargeable battery cells, etc., in a battery housing, and evaluating the status of the battery cells.

### Description of the Related Art

Generally, in a conventional battery housing, individual battery cells are welded together. Conventional battery housings may include a sensor in contact with the welded battery cells that obtains status information regarding an aggregated temperature, voltage, and current for all of the battery cells included in the battery housing.

### BRIEF SUMMARY

The present disclosure is directed to embodiments of a battery housing that includes one or more sensors that each sense status data for a battery. For example, in at least one embodiment of a battery management system of the present disclosure, a battery housing has one or more contacts and a lid for the battery housing has one or more lid contacts, wherein the lid is movable such that at least one battery contact in contact with a lid contact and a battery housing contact is disengaged from the lid contact. The battery housing may contain two or more battery cells, where at least one of the battery cells is able to be removed without removing another battery cell of the two or more battery cells. One or more sensors may be electronically coupled to a lid contact, and the one or more sensors may be configured to sense status data associated with a single battery cell in contact with the lid contact.

In operation, the battery management system may include a microprocessor and at least one multiplexer that is electronically coupled to the microprocessor and at least one sensor of the one or more sensor. The at least one sensor may transmit data to the microprocessor via the multiplexer.

In operation, the microprocessor may generate information regarding the status of two or more battery cells based on data received from the one or more sensors. The information regarding the status of the two or more battery cells may be displayed to a user via a battery management user interface. In some embodiments, each sensor may be associated with an identifier. The identifier may indicate a location of the sensor, an individual battery cell, a group of battery cells, or some combination thereof.

The one or more sensors may sense data associated with at least one of: a voltage of a battery cell associated with the sensor; a temperature of a battery cell associated with the sensor; or a current of a battery cell associated with the sensor.

In some embodiments, a sensor senses data associated with a battery cell when the battery cell is charging, discharging, or some combination thereof.

In operation, the lid of the battery management system may be moveable from a first position to a second position to allow for the removal, addition, replacement, or some combination thereof, of a battery cell. The lid may be movable back to the first position from the second position. In some embodiments, the lid is mechanically connected to the battery housing.

In some embodiments, at least a portion of the sensors may be positioned above electrodes of the lid contacts. In some embodiments, at least a portion of the sensors may be positioned below electrodes of the lid contacts.

A battery management software system may comprise at least one processor and at least one non-transitory memory storing processor-executable instructions. The processor-executable instructions may cause the processor to receive data from one or more sensors of a battery housing regarding the status of two or more battery cells included in the battery housing. The processor may further be caused to present data from the one or more sensors to a user via a battery management user interface.

In some embodiments, the processor is caused to receive a selection of at least one battery cell and display data regarding the status of the at least one battery via the battery management user interface based on the selection of the at least one battery cell.

In some embodiments, the processor is caused to determine whether at least one battery cell is to be replaced based on data regarding the status of the at least one battery cell. The processor may further be caused to display an indication that the battery cell is to be replaced via the battery management user interface.

In some embodiments, a method of operating a battery management system includes placing two or more battery cells in a battery housing such that the battery cells are each able to be in contact with a lid contact of a lid of the battery housing and a battery housing contact of the battery housing, the lid being movable such that as few as one battery cells are able to be removed, added, or replaced from the battery housing. The method may further include receiving data regarding the status of at least one battery cell from a sensor in contact with a lid contact or a battery housing contact. The method may further include displaying data regarding the status of the at least one battery cell via a battery management user interface.

In some embodiments, the method includes transmitting, by one or more sensors, data regarding the status of at least one battery cell to at least one processor via a multiplexer.

In some embodiments, the method includes determining whether at least one battery cell is to be replaced based on data regarding the status of the at least one battery cell; moving the lid to expose the at least one battery cell; replacing the battery cell with a new battery cell; and replacing the lid.

In some embodiments, the method includes receiving status data of the at least one battery cell from at least one sensor when the battery is charging, discharging, or some combination thereof.

### BRIEF DESCRIPTION OF THE SEVERAL VIEWS OF THE DRAWINGS

For a better understanding of the embodiments, reference will now be made by way of example to the accompanying drawings. In the drawings, identical reference numbers identify the same or similar elements or acts unless the context indicates otherwise. The sizes and relative proportions of the elements in the drawings are not necessarily drawn to scale. For example, some of these elements may be enlarged and positioned to improve drawing legibility.

FIG. 1A is a perspective view of an embodiment of components of a battery housing with a removable lid, in which the lid, a circuit board, and the battery housing are each separated from one another;

FIG. 1B is a perspective view of the embodiment of the battery housing, in which the lid and circuit board are in contact with one another, and in which the lid and circuit board are separated from the battery housing;

FIG. 1C is a perspective view of the embodiment of the battery housing in which lid contacts are shown on the underside of the lid, and in which the lid is separated from the battery housing;

FIG. 1D is a perspective view of the embodiment of the battery housing, in which assembly of the components of the battery housing is shown;

FIG. 2 is a perspective view of the embodiment of the battery housing as shown in FIGS. 1A-1D with some respective components hidden such that internal components are visible, and in which sensors are in electrical contact with a contact of the lid or battery housing, and in which the battery is in contact with the contact of the lid or battery housing;

FIG. 3A is a perspective view of the embodiment of the battery housing as shown in FIGS. 1A-1D with some respective components hidden such that internal components are visible, and in which the lid of the battery housing includes a circuit board for obtaining data from one or more sensors;

FIG. 3B is a circuit diagram of an embodiment of a circuit board for obtaining data from one or more sensors;

FIG. 4 is a display diagram of an embodiment of a user interface for a battery management system; and

FIG. 5 is a flow diagram of a process used in an embodiment of a battery management system for determining whether a battery cell is to be replaced.

### DETAILED DESCRIPTION

In the following description, certain specific details are set forth in order to provide a thorough understanding of various embodiments of the disclosure. However, one skilled in the art will understand that the disclosure may be practiced without these specific details. In other instances, well-known structures and components associated with battery management devices or systems or utilizing battery management devices or systems have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second, third, fourth, etc., does not necessarily imply a ranked sense of order, but rather may only distinguish between multiple instances of an act or structure.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terms “top,” “upper,” “lower,” “left,” and “right,” are used for only discussion purposes based on the orientation of the components in the discussion of the figures in the present disclosure as follows. These terms are not limiting as to the possible positions explicitly disclosed, implicitly disclosed, or inherently disclosed in the present disclosure.

The term “substantially” is used to clarify that there may be slight differences or variations as for when a surface is coplanar with another surface in the real world, as nothing can be made perfectly equal or perfectly the same. In other words, substantially means that there may be some slight variation in actual practice, and instead, is made within accepted tolerances.

As used in this specification and the appended claims, the singular forms “a,” “an,” and “the” include plural referents unless the content clearly dictates otherwise.

Generally, in a conventional battery management system, a battery housing includes a group of battery cells that are soldered together and a sensor that senses data associated with the group of battery cells. The sensor is electronically connected to a processor or computing device, such as via a wire extending from the battery housing in which the sensor and battery cells are contained to the processor or computing device. The data received from the sensor, such as temperature, voltage, current, etc., of the battery cells, represents an aggregated status of each battery cell in the group of battery cells.

However, such conventional systems are unable to receive data representing the status of a single battery cell of the group of battery cells, because the sensor is electronically connected to a group of battery cells that are soldered together. Furthermore, especially in the case of the measured current, the sensor is not able to adequately detect accurate status data for individual battery cells in the group of battery cells because the sensor is effectively connected to all of the battery cells and is thus only receiving aggregated status data for the entire group. Thus, conventional systems are not able to detect whether a single battery cell has degraded to a point where it is to be replaced.

Additionally, because battery cells in conventional systems are soldered together, it is not possible to replace an individual battery cell that has degraded with a newer battery cell. As a result, conventional systems must either replace the entire group of battery cells when one battery cell has degraded, or implement specialized software and hardware to bypass battery cells that are suspected to be degraded, instead of simply replacing the degraded battery cells with new battery cells.

In view of the above discussion with the conventional battery management systems, the present disclosure is directed to embodiments of a battery management device or systems that avoid or prevent the issues as discussed above with respect to the conventional battery management systems. For example, in at least one embodiment of a battery management system of the present disclosure, one or more sensors are included in a battery housing, such as in a movable lid of the battery housing, and each of the sensors are positioned such that they are able to receive status data for a subset of the battery cells (such as a single battery cell) inside of the battery housing. Furthermore, the battery cells are not soldered together, and are instead held in place frictionally by other battery cells, mechanical means, by structures inside of the battery housing, other methods of holding a battery cell in place, or some combination thereof. When a battery cell is detected to have degraded past a certain amount, based on data received from a sensor associated with the battery, the lid is able to be moved to expose the battery cell and an operator may remove or replace the battery cell with a new battery cell.

In operation, the battery management system may receive data associated with at least a subset of battery cells included in a battery housing from one or more sensors. The data received from the one or more sensors may be used to determine whether at least one battery cell is to be replaced. A lid of the battery housing may be moved to expose the battery cell and allow for the removal, replacement, or some combination thereof, of the battery cell. In some embodiments status data associated with the battery cells is displayed to a user via a battery management user interface.

In view of the above discussion, the battery management system disclosed herein improves conventional methods, devices, and systems of battery management by avoiding or preventing the issues with the conventional battery management systems as discussed above.

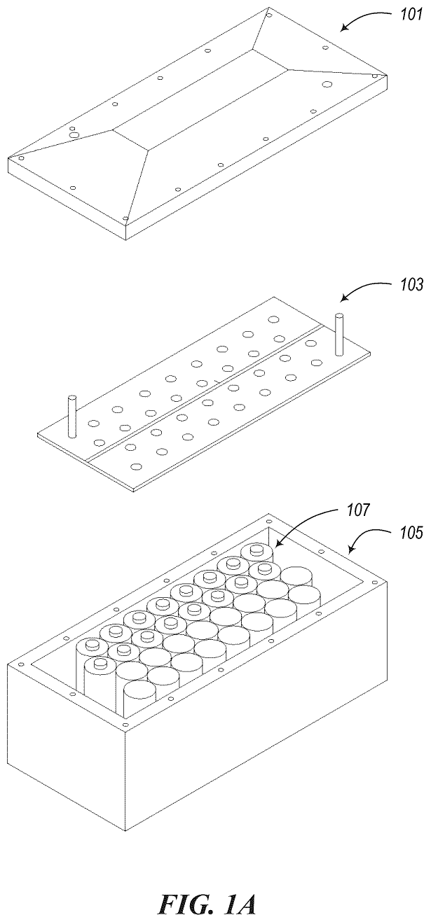

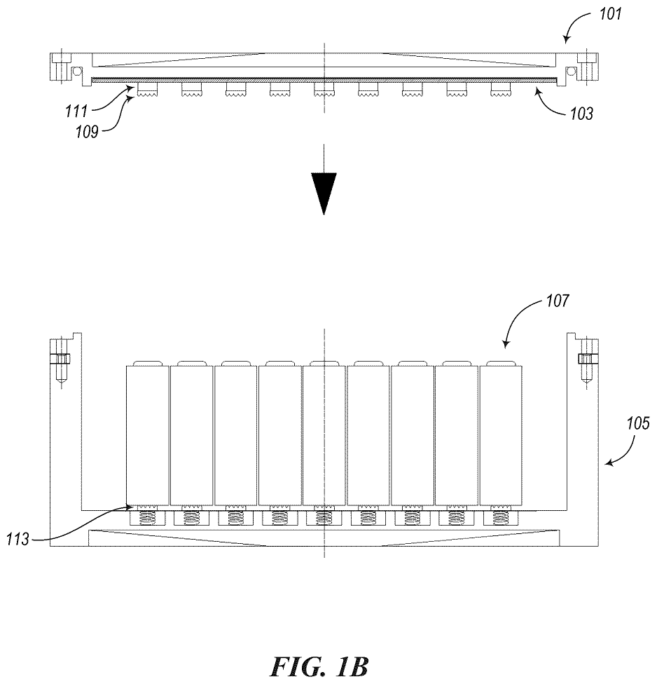

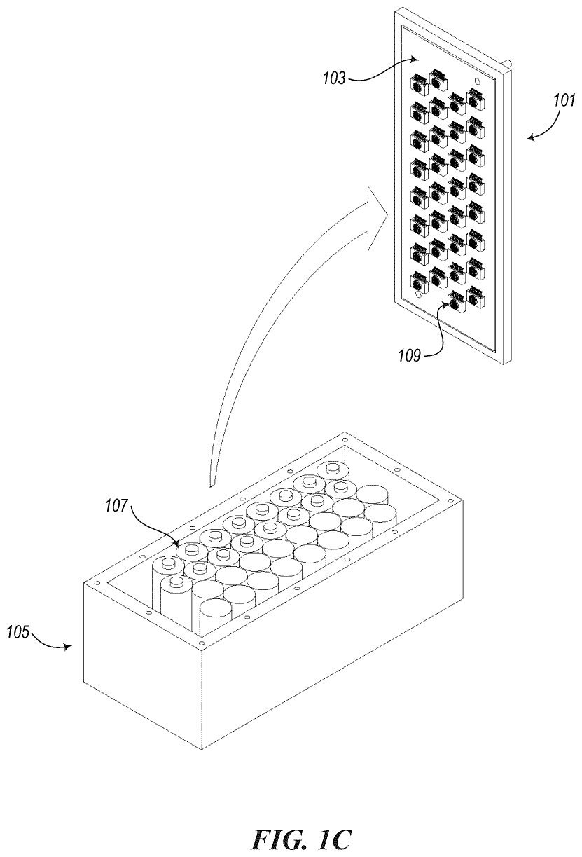

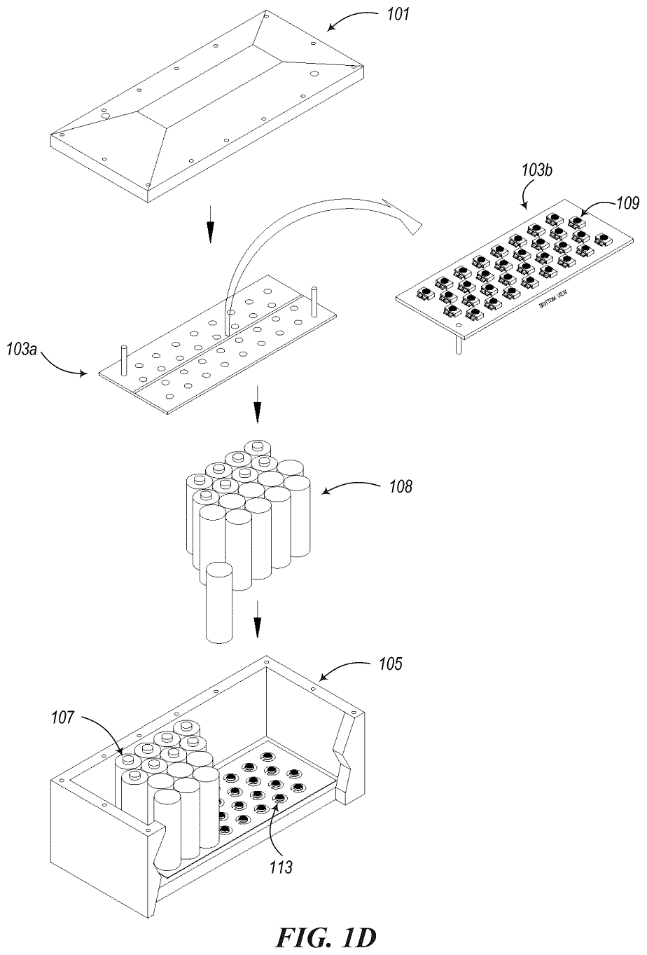

FIG. 1A is a perspective view of an embodiment of components of a battery housing with a removable lid, in which the lid 101, a circuit board 103, and the battery housing 105 are each separated from one another. The battery housing 105 may contain one or more battery cells 107. In some embodiments, the circuit board 103 is included in the lid 101, is the lid 101, is not detachable from the lid 101, is separated from the lid 101, or some combination thereof. In some embodiments, the lid 101 is attached to the battery housing 105, but can be detached or moved, such that the lid 101 exposes the interior of the battery housing 105. For example, the lid 101 may be attached to the battery housing 105 via a hinge, may be able to slide into or out of the battery housing 105, may be mechanically attached to the battery housing (such as via one or more screws, nuts, bolts, pins, or other mechanical connections), or otherwise attached to the battery housing 105 such that it is movable to expose the interior of the battery housing 105 where the battery cells 107 are housed. In some embodiments, the circuit board 103 is included in the battery housing 105. In some embodiments, one or more of the lid 101 and circuit board 103 may be located on top, on the bottom, on one or more of the sides, or some combination thereof, of the battery housing 105. The battery cells 107 may each have battery contacts, such that the battery cells 107 are able to be in electrical contact with a lid contact, a battery housing contact, a contact of another battery cell, or some combination thereof.

In some embodiments, the battery cells 107 may include rechargeable battery cells, disposable battery cells, or some combination thereof. In some embodiments, the battery cells 107 include lithium-ion battery cells, lithium iron phosphate battery cells, other types of battery cells, or some combination thereof. In an example embodiment, the battery cells 107 are each rechargeable battery cells.

In some embodiments, one or more conductive pieces, such as wires, pieces of metal (such as metal rods), or other conductive pieces, may be attached to the lid 101, the circuit board 103, or some combination thereof. In some such embodiments, the conductive pieces may be connected to the circuit board 103 and may pass through one or more holes in the lid 101, such that a portion of the conductive pieces stick out from the lid 101. The one or more conductive pieces may be used to conduct electricity through, into, from, or some combination thereof, the battery cells 107 via lid contacts.

FIG. 1B is a perspective view of the embodiment of the battery housing 105, in which the lid 101 and circuit board 103 are in contact with one another, and in which the lid 101 and circuit board 103 are separated from the battery housing 105. The circuit board 103 may be electronically connected to one or more of the sensors 111. One or more of the sensors 111 may be electronically connected to one or more lid contacts 109. The battery cells 107 may be positioned inside of the battery housing 105 such that they are in electrical contact with battery housing contacts 113. The lid 101 may be positioned such that one or more lid contacts 109 are in electrical contact with one or more contacts of the battery cells 107. In some embodiments, the battery cells 107 are placed in the battery housing 105, such that they frictionally hold each other in place. In some embodiments, individual battery cells 107 are mechanically contained within the battery housing 105, such as by using a clamp, screw, pin, bolt, other means of mechanical connection, or some combination thereof. The battery cells 107 may be placed inside of the battery housing 105 such that individual battery cells may be removed from the battery housing 105 without removing other battery cells from the battery housing 105.

In some embodiments, the sensors 111 are positioned such that they are in electrical contact with a contact of a battery cell and a lid contact 109. In some embodiments, the sensors 111 are positioned such that they are in electrical contact with a lid contact 109, but not with a contact of a battery cell. In some embodiments, the circuit board 103 is included in the battery housing 105 instead of the lid 101. In some embodiments where the circuit board 103 is included in the battery housing 105, the sensors 111 may be positioned such that they are in electrical contact with a battery housing contact 113 and a battery contact. In some embodiments where the circuit board 103 is included in the battery housing 105, the sensors 111 may be positioned such that they are in electrical contact with a battery housing contact 113 and not in electrical contact with a battery contact. In some embodiments, the one or more of the sensors 111 senses data associated with a battery cell when the battery cell is charging, discharging, or some combination thereof.

FIG. 1C is a perspective view of the embodiment of the battery housing 105 in which lid contacts 109 are shown on the underside of the lid 101, and in which the lid 101 is separated from the battery housing 105. While the embodiment depicted in FIG. 1C shows the lid 101 being completely separated from the battery housing 105, embodiments are not so limited, and in some embodiments, the lid 101 may be moved such that it is still attached to the battery housing 105, but the battery cells 107 may still be exposed when the lid 101 is moved.

FIG. 1D is a perspective view of the embodiment of the battery housing 105, in which assembly of one or more components of the battery housing 105 is shown. The lid 101 may be attached to the circuit board 103. In some embodiments, attaching the lid 101 to the circuit board 103 leaves at least a portion of one or more conductive pieces exposed above the lid 101. The top of the circuit board is depicted as circuit board 103a in FIG. 1D, and may include one or more conductive pieces. The bottom of the circuit board is depicted as 103b in FIG. 1D, and may include one or more sensors and one or more lid contacts 109.

Battery cells 108 and 107 are depicted in FIG. 1D as being able to be placed inside of or removed from the battery housing 105. Although FIG. 1D depicts multiple battery cells being placed inside of or removed from the battery housing 105, embodiments are not so limited, and individual battery cells may be placed inside of or removed from the battery housing 105. The battery housing may have battery housing contacts 113 placed such that battery cells 108 and 107 are electrically in contact with the battery housing contacts 113 when the battery cells 108 and 107 are placed inside of the battery housing 105. The lid contacts 109 may be electrically in contact with the battery cells 108 and 107, such as when the lid is positioned on top of the battery housing 105.

In an example embodiment, the lid 101 includes the circuit board 103, and a respective sensor 105 of the circuit board 103 is electrically in contact with a respective lid contact 109. In the example embodiment, the circuit board 103 may include sensors, such as sensors 111, that are each in electrical contact with at least one lid contact 109. In the example embodiment, one or more battery cells, such as the battery cells 107 and 108 may be placed inside of the battery housing 105, such that each respective battery cell is in electrical contact with a respective battery housing contact 113. In the example embodiment, the lid 101 may be positioned onto the battery housing 105, such that each respective lid contact 109 is electrically in contact with a respective battery cell. In the example embodiment, the lid 101 may be moved such that at least one of the battery cells is able to be removed from or placed into the battery housing 105. The lid 101 may then be repositioned onto the battery housing 105.

In some embodiments, a battery cell may be removed from the battery housing 105 without replacing the battery cell. In such embodiments, at least one lid contact 109, at least one battery housing contact 113, at least one sensor 111, or some combination thereof, may not be in electrical contact with any battery cell.

In some embodiments, the battery housing 105 includes multiple circuit boards 103, multiple lids 103, or some combination thereof.

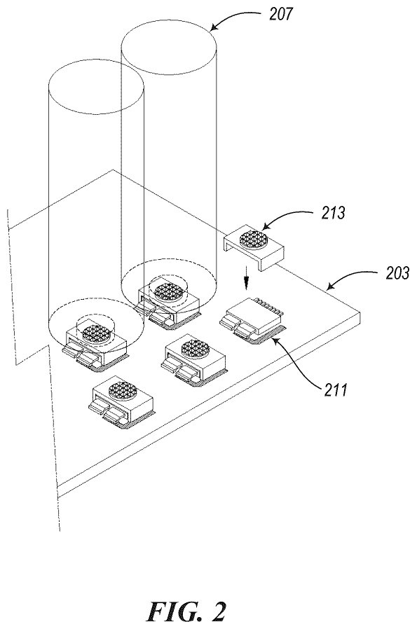

FIG. 2 is a perspective view of the embodiment of the battery housing 105 as shown in FIGS. 1A-1D with some respective components hidden such that internal components are visible, and in which sensors 211 are in electrical contact with a contact 213 of the lid 101 or battery housing 105, and in which the battery cell 207 is in electrical contact with the contact 213 of the lid 101 or battery housing 105. In some embodiments, the contact 213 is a lid contact. In some embodiments, the contact 213 is a battery housing contact. In some embodiments, the sensor 211 is positioned in between the contact 213 and the battery cell 207. In some embodiments, the contact 213 and sensor 203 are electrically connected to a circuit board 203.

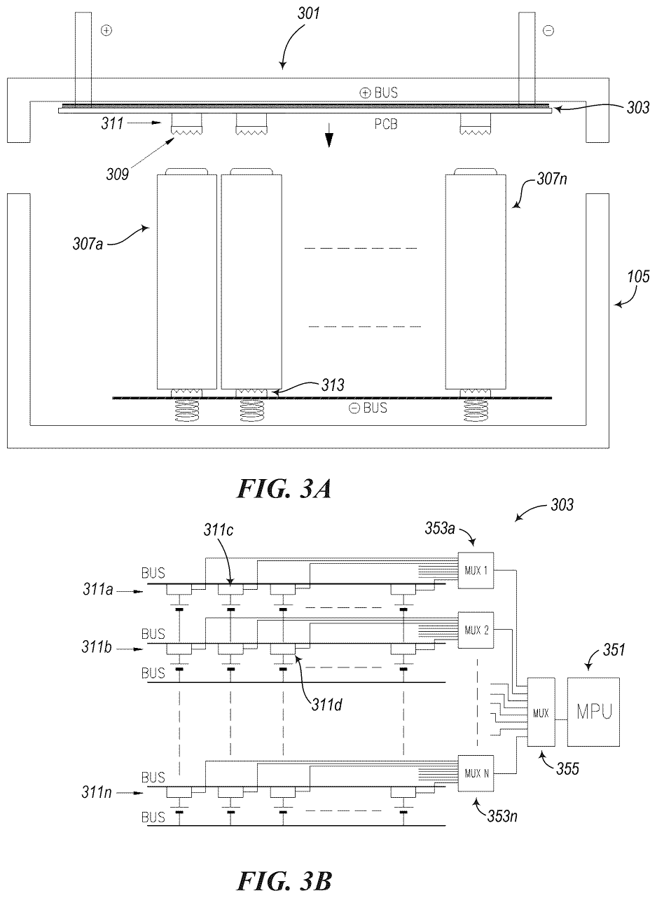

FIG. 3A is a perspective view of the embodiment of the battery housing 105 as shown in FIGS. 1A-1D with some respective components hidden such that internal components are visible, and in which the lid 301 of the battery housing 105 includes a circuit board 303 for obtaining data from one or more sensors 311. The sensors 311 may each be electrically connected to a contact, such as a lid contact 309, a battery housing contact 313 (not shown), other contacts (not shown), or some combination thereof. The battery housing 105 additionally includes housing contacts 313. The housing contacts 313 and lid contacts 309 may be electronically connected to a battery cell 307, for example, by placing a battery cell such that it is directly contacting at least one housing contact 313 and at least one lid contact 309. The battery housing 105 may receive a positive charge from at least one conductive element, a negative charge from at least one conductive element, or some combination thereof.

FIG. 3B is a circuit diagram of an embodiment of a circuit board 303 for obtaining data from one or more sensors 311. The circuit board 303 includes one or more sensors 311a-311n (collectively “sensors 311” or individually as “sensor 311”), one or more secondary multiplexers 353a-353n (collectively “multiplexers 353” or individually as “multiplexer 353”), a one or more primary multiplexers 355, and a processor 351. The processor 351 may be one or more processors for executing computer programs, such as a CPU, GPU, TPU, NNP, FPGA, MPU, or ASIC.

Each of the sensors 311 is in electrical contact with at least one contact of a battery housing, and thus may sense data associated with a battery cell that is in electrical contact with the at least one contact. In some embodiments, the sensors 311 are configured such that they are each able to sense data associated with a single battery cell of a plurality of battery cells included in the battery housing. In some embodiments, the data associated with a single battery cell is used to determine status indicators of the battery cell: a usage time of the battery cell, a battery voltage of the battery cell, a battery current of the battery cell, a remaining capacity of the battery cell, an average current of the battery cell, a maximum current of the battery cell, a minimum current of the battery cell, a current capacity of the battery cell, a temperature of the battery cell, a state of the health of the battery cell, a state of the charge of the battery cell, or some combination thereof. In some such embodiments, the processor 351 determines one or more of the status indicators of the battery cell. In some embodiments, the sensor directly senses one or more of the status indicators of the battery cell.

The sensors 311 may optionally transmit data to the processor 351 via one or more multiplexers, such as a secondary multiplexer 353, a primary multiplexer 355, other multiplexers, or some combination thereof. The data transmitted by each of the sensors 311 via the multiplexer may include an identifier for the sensor 311 that transmitted the data, such that the data received from each individual sensor can be identified. By operating in this manner, the processor 351, a computing device separate from the processor 351, or some combination thereof, is able to associate status indicators of a battery cell with a particular battery cell, instead of attributing the status indicators to each of the battery cells.

In some embodiments, the battery housing 105 includes multiple types of sensors that are each configured to sense data associated with one or more selected status indicators of a battery cell, such as a sensor that senses temperature, a sensor that senses voltage, a sensor that senses current, a sensor that senses some combination of temperature, current, and voltage, etc. In such embodiments, one or more of the sensors may be able to sense data associated with a single battery cell, data associated with multiple battery cells, or some combination thereof. In some such embodiments, the battery housing 105 may have one sensor that senses data for all of the battery cells, such as, for example, a single temperature sensor that senses the temperature inside of the battery housing.

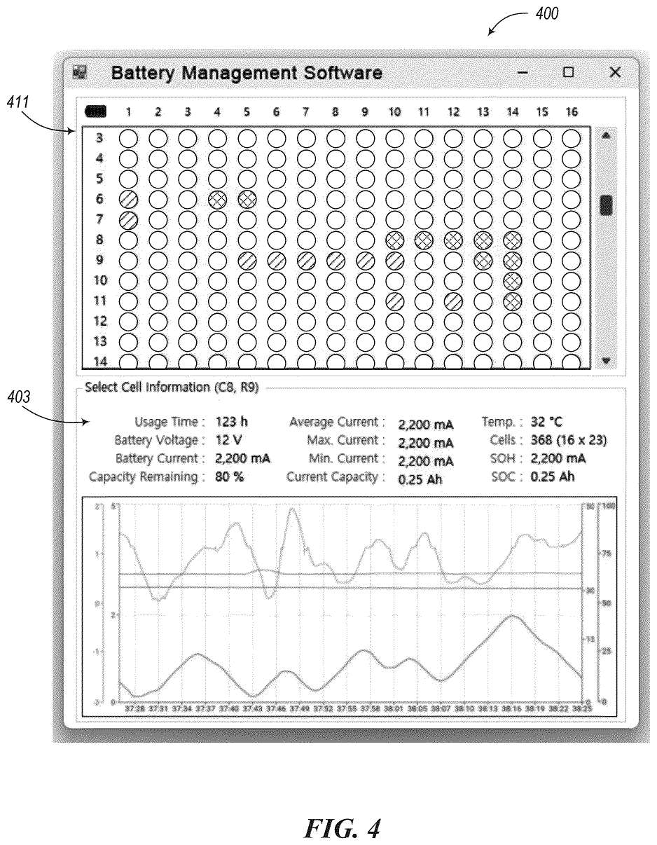

FIG. 4 is a display diagram of an embodiment of a user interface 400 for a battery management system. The user interface 400 includes a battery cell location plot 401, and a battery cell information section 403. The battery cell location plot 401 depicts a location of one or more battery cells included in a battery housing, such as the battery housing 105 described above in connection with FIG. 1. In some embodiments, the depiction of the location of the battery cell may changed to indicate the status of a battery cell, such as whether the battery cell should be replaced, will likely be replaced soon, does not need to be replaced.

In the battery cell location plot 401, a blank circle indicates a battery cell that is “healthy” (i.e. does not need to be replaced soon), a circle filled with right-to-left diagonal lines indicates a battery cell that is in “moderate health” (i.e. the battery cell will need to be replaced soon), and a cross-hatched circle indicates a battery cell that is in “bad health” (i.e. the battery cell should be replaced). In some embodiments, the battery cell location plot 401 indicates the health of battery cells with various colors, such as red, green, blue, yellow, etc. Although the battery cell location plot 401 shows three status types for battery cells, embodiments are not so limited, and the battery cell location plot 401 may show more than three or less than three status types for battery cells. Furthermore, while the battery cell location plot 401 shows an “overall” status indicator of health for battery cells, embodiments are not so limited, and other embodiments may depict other statuses of the battery cells related to any one or more status indicators of a battery cell.

In some embodiments, selecting a depiction of a battery cell in the battery cell location plot 401 populates the battery cell information section 403 with data associated with the status of the battery cell, such as data sensed by a sensor in a battery housing. The battery cell information section 403 may include data associated with one or more status indicators of a battery cell, such as the status indicators described above in connection with FIG. 3.

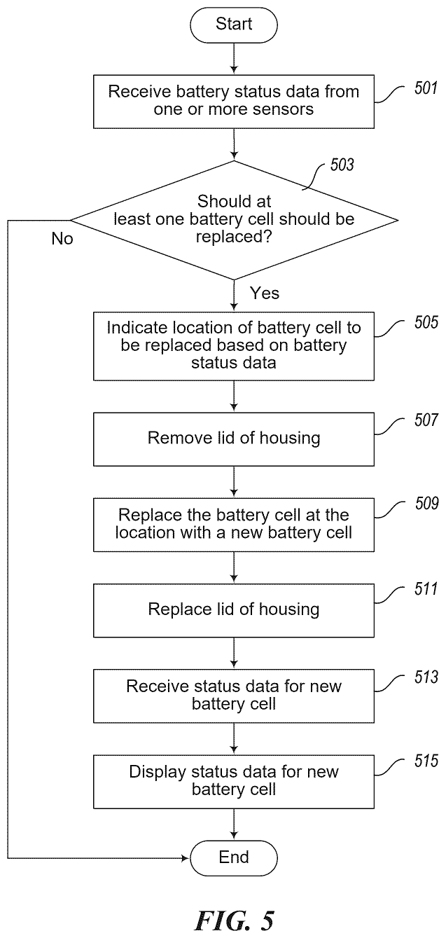

FIG. 5 is a flow diagram of a process 500 used in an embodiment of a battery management system for determining whether a battery cell is to be replaced. In some embodiments, the process 500 is performed by one or more processors that receives sensor data from batteries, such as the processor 351 described above in connection with FIG. 3B. In some embodiments, the process 500 is performed by a computing device that receives sensor data from one or more sensors included in a battery housing, such as via the processor 351 described above in connection with FIG. 3B, directly from sensors electronically connected to contacts of the battery housing, or some combination thereof. For ease of description, the process 500 is described below as being performed by a single processor, however, embodiments are not so limited, and aspects of the process 500 may be performed by multiple processors, one or more computing devices, or some combination thereof.

The process 500 begins, after a start block, at act 501, where a processor receives status data indicating the status of one or more battery cells in a battery housing. The processor may receive status data via one or more sensors, such as the sensors 111, 211, or 311, described above in connection with FIGS. 1, 2, and 3 respectively.

The process 500 proceeds to act 503, where the processor determines whether at least one battery cell should be replaced based on the battery status data. In some embodiments, the processor determines whether at least one battery cell should be replaced based on historical battery status data received from one or more sensors over a period of time. In some embodiments, one or more statistical analysis techniques are applied to the battery status data to determine whether at least one battery cell is to be replaced. In some embodiments, the battery status data is applied to one or more selected performance benchmarks for battery status indicators to determine whether at least one battery cell is to be replaced. In some embodiments, the processor utilizes a combination of statistical analysis and performance indicators to perform act 503.

If the processor determines that at least one battery cell should be replaced, the process 500 proceeds to act 505, otherwise the process 500 ends.

At act 505, the processor indicates a location of the battery cell to be replaced based on the battery status data. In some embodiments, the location of the battery cell is indicated via a user interface, such as the user interface 400 described above in connection with FIG. 4. In some embodiments, the location of the battery cell is indicated via one or more indicators associated with a battery housing, such as by illuminating a light associated with the location of the battery cell. In some such embodiments, the light is included in the battery housing. In embodiments where a light indicates the location of the battery cell, the user interface 400 may or may not be used. In such embodiments, one or more lights may indicate one or more status indicators of one or more battery cells.

The process 500 proceeds to act 507, where the lid of the battery housing is moved. In some embodiments, the lid of the battery housing is moved automatically, such as by causing a signal to be transmitted to the battery housing to move the lid via motor or another means, causing a signal to be transmitted to a robot to move the lid, other methods of moving a lid of a battery housing, or some combination thereof. In some embodiments, where the battery housing is at least partially submerged for a period of time, such as in a cooling liquid, the processor causes a signal to move the battery housing before the lid is moved to be transmitted, such as to a device that raises or lowers the battery housing into the liquid. In some embodiments, the lid is moved by a user.

The process 500 proceeds to act 509, where the battery cell at the location is replaced with a new battery. In some embodiments, a user removes the battery cell and replaces the battery cell with a different battery cell. In some embodiments, the battery cell is removed, replaced, or some combination thereof, through an automatic means, such as by a motor, a robot, or other automatic means to remove or replace a battery. In some embodiments, the battery cell at the location is removed, but is not replaced with a different battery cell.

The process 500 proceeds to act 511, where the lid of the battery housing is replaced. Act 511 may be performed in a similar manner to act 507. In embodiments where the battery housing is at least partially submerged for a period of time, the battery housing may be caused to be resubmerged at least partially.

The process 500 proceeds to act 513, where the processor receives status data for the new battery cell. Act 513 may be performed in a similar manner to act 501.

The process 500 proceeds to act 515, where the processor causes the status data for the new battery cell to be displayed, such as by using the user interface 400 described above in connection with FIG. 4.

After act 515, the process 500 ends.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A battery management system, comprising:
a battery housing having one or more contacts;
two or more battery cells, each battery cell being in contact with at least one contact of the one or more contacts of the battery housing, each battery cell of the two or more battery cells also having at least one battery contact, wherein at least one battery cell of the two or more battery cells able to be removed without removing another battery cell of the two or more battery cells;
a lid for the battery housing having one or more lid contacts, wherein the lid is configured to be positioned on the battery housing such that at least one battery contact of at least one battery cell of the two or more battery cells is in contact with at least one lid contact of the one or more lid contacts, and wherein the lid is moveable such that the at least one battery contact disengages with the at least one lid contact; and
one or more sensors, wherein at least one sensor of the one or more sensors is electronically coupled to at least one lid contact, each sensor of the one or more sensors being configured to sense data related to the status of one battery cell in contact with a lid contact.

2. The battery management system of claim 1, further comprising:
at least one microprocessor; and
at least one multiplexer electronically coupled to the at least one microprocessor and the one or more sensors, wherein the sensors transmit data to the at least one microprocessor via the at least one multiplexer.

3. The battery management system of claim 2, wherein the at least one microprocessor is further configured to:
generate information regarding the status of the one or more battery cells based on data received from the one or more sensors via the at least one multiplexor; and
cause the information regarding the status of the two or more battery cells to be displayed to a user via a battery management system user interface.

4. The battery management system of claim 2, wherein each sensor of the one or more sensors is associated with an identifier, and wherein each sensor of the one or more sensors transmits an indication of the identifier to the at least one microprocessor via the at least one multiplexor.

5. The battery management system of claim 1, wherein each sensor of the one or more sensors senses:
a current of a battery cell associated with the sensor.

6. The battery management system of claim 1, wherein each sensor of the one or more sensors senses data associated with a battery cell associated with the sensor when the battery cell is charging.

7. The battery management system of claim 1, wherein each sensor of the one or more sensors senses data associated with a battery cell associated with the sensor when the battery cell is discharging.

8. The battery management system of claim 1, wherein the lid is moveable from a first position to a second position to allow for the replacement of a battery cell, and wherein the lid is moveable back to the first position from the second position after the battery cell is replaced.

9. The battery management system of claim 8, wherein the lid is mechanically connected to the battery housing.

10. The battery management system of claim 1, wherein the one or more sensors are positioned below electrodes of the one or more lid contacts.

11. The battery management system of claim 1, wherein the one or more sensors are positioned above electrodes of the one or more lid contacts.

12. A battery management software system, comprising:
at least one processor; and
at least one non-transitory memory storing processor-executable instructions that cause the at least one processor to:
receive data from one or more sensors regarding the status of two or more battery cells included in a battery housing having a removable lid, the battery housing including the one or more sensors, each sensor of the one or more sensors being able to sense data associated with a current of one battery cell of the two or more battery cells; and
present the data from the one or more sensors to a user via a battery management user interface.

13. The battery management software system of claim 12, wherein the processor-executable instructions further cause the at least one processor to:
identify data regarding the status of a battery cell of the two or more battery cells based on at least one identifier received from the one or more sensors via a multiplexor.

14. The battery management software system of claim 12, wherein the processor-executable instructions further cause the at least one processor to:
receive, via the battery management user interface, a selection of at least one battery cell of the two or more batteries; and
display, via the battery management user interface, data regarding the status of the at least one battery cell based on the selection of the at least one battery cell and the data regarding the status of the two or more battery cells.

15. The battery management software system of claim 12, wherein the processor-executable instructions further cause the at least one processor to:
determine, based on the data regarding the status of the two or more battery cells, whether at least one battery cell of the two or more battery cells are to be replaced; and
display, via the battery management user interface, an indication that the at least one battery cell is to be replaced.

16. A method, comprising:
placing two or more battery cells in a battery housing having one or more bottom housing contacts and a lid for the battery housing having one or more lid contacts, wherein the lid is able to be positioned on the battery housing such that at least one battery contact for at least one battery cell of the one or more batteries is in contact with at least one lid contact of the one or more lid contacts, and wherein the battery housing includes at least one sensor electronically connected with at least one contact of the battery housing, the at least one sensor being configured to sense data associated with one battery cell of the two or more battery cells, and wherein at least one battery cell of the two or more battery cells able to be removed without removing another battery cell of the two or more battery cells;
receiving data regarding the status of the at least one battery cell from the at least one sensor; and
displaying the data regarding the status of the at least one battery cell via a battery management user interface.

17. The method of claim 16, wherein the method further comprises:
transmitting, by the one or more sensors, data regarding the status of the at least one battery cell to at least one processor via multiplexor.

18. The method of claim 16, wherein the method further comprises:
determining, based on the data regarding the status of the at least one battery cell, whether the at least one battery cell is to be replaced;
moving the lid for the battery housing to expose the at least one battery cell;
replacing the at least one battery cell with a new battery cell; and
replacing the lid for the battery housing.

19. The method of claim 16, wherein the method further comprises:
receiving data regarding the status of the at least one battery cell from the at least one sensor when the at least one cell battery is charging.

20. The method of claim 16, wherein the method further comprises:
receiving data regarding the status of the at least one battery cell from the at least one sensor when the at least one battery cell is discharging.
